(19) United States
(12) Patent Application Publication
(10) Pub. No.: US 2026/0344003 A1
(43) Pub. Date: Oct. 29, 2026

(54) COMPLEMENTARY FIELD-EFFECT TRANSISTOR DEVICES AND METHODS OF FORMING

(71) Applicant: Taiwan Semiconductor Manufacturing Co., Ltd., Hsinchu (TW)

(72) Inventors: Kuan-Kan Hu, Hsinchu (TW); Yung-Ta Chen, Taichung City (TW); Ku-Feng Yang, Baoshan Township (TW); Szuya Liao, Zhubei (TW)

(21) Appl. No.: 19/732,480

(22) Filed: Jul. 6, 2026

Related U.S. Application Data
(63) Continuation of application No. 19/060,450, filed on Feb. 21, 2025.
(60) Provisional application No. 63/719,195, filed on Nov. 12, 2024.

(51) Int. Cl. H10D 80/30; H10D 84/01; H10D 84/85; H10W 80/00; H10W 90/00

(52) U.S. Cl. CPC H10D 80/30; H10D 84/0167; H10D 84/017; H10D 84/0188; H10D 84/851; H10W 90/00; H10W 80/211; H10W 80/312; H10W 80/327; H10W 90/792

(57) ABSTRACT

A method of forming a semiconductor device includes: forming a self-aligned material (SAM) on a surface of a conductive feature of an interconnect structure, where the interconnect structure is formed at a first side of a device layer that includes a transistor, where the conductive feature is embedded in an outermost dielectric layer of the interconnect structure distal from the device layer, and the surface of the conductive feature is exposed by the outermost dielectric layer; after forming the SAM, selectively forming a dielectric layer on the outermost dielectric layer of the interconnect structure; and after selectively forming the dielectric layer, removing the SAM from the surface of the conductive feature, where after removing the SAM, the dielectric layer extends further from the device layer than the conductive feature.

### PRIORITY CLAIM AND CROSS-REFERENCE

This application is a continuation of U.S. patent application Ser. No. 19/060,450, filed Feb. 21, 2025 and entitled “Complementary Field-Effect Transistor Devices and Methods of Forming,” which application claims priority to U.S. Provisional Patent Application No. 63/719,195, filed Nov. 12, 2024 and entitled “SAM Assisted Multi-Dimension Metal Hybrid Bonding for Parallel CFET,” which applications are hereby incorporated by reference in their entireties.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

Recently, vertically stacked transistor devices, such as complementary field-effect transistor (CFET) devices, provide a promising new architecture that achieves improved integration density by forming nanostructure field-effect transistors (NSFETs) that are vertically stacked over a substrate. Various aspects of this new architecture need to be studied and improved to achieve better device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 5C, 6A, 6B, 6C, 7A, 7B, 7C, 8A, 8B, 9A, 9B, 10A, 10B, 11A, 11B, 12A, 12B, 13A, 13B, 13C, 14A, 14B, 15A, 15B, and 15C illustrate various views of a complementary field-effect transistor (CFET) device at various stages of manufacturing, in accordance with an embodiment.

FIGS. 16, 17A, and 17B illustrate cross-sectional views of a CFET device at various stages of manufacturing, in accordance with another embodiment.

FIG. 18 illustrates a flow chart of a method of forming a semiconductor device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

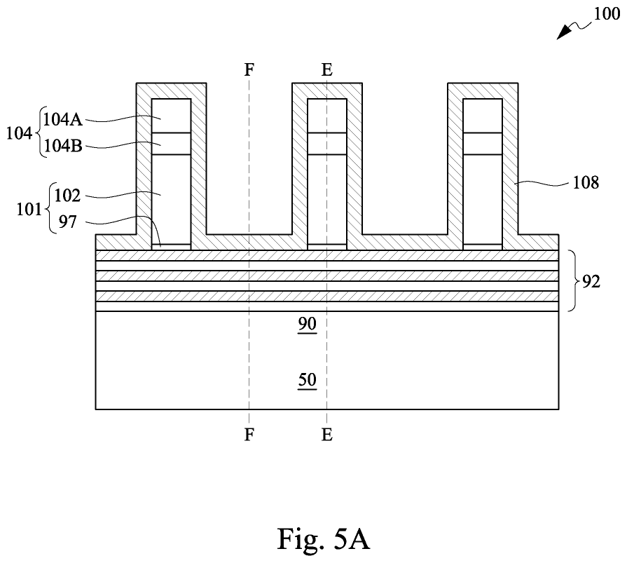

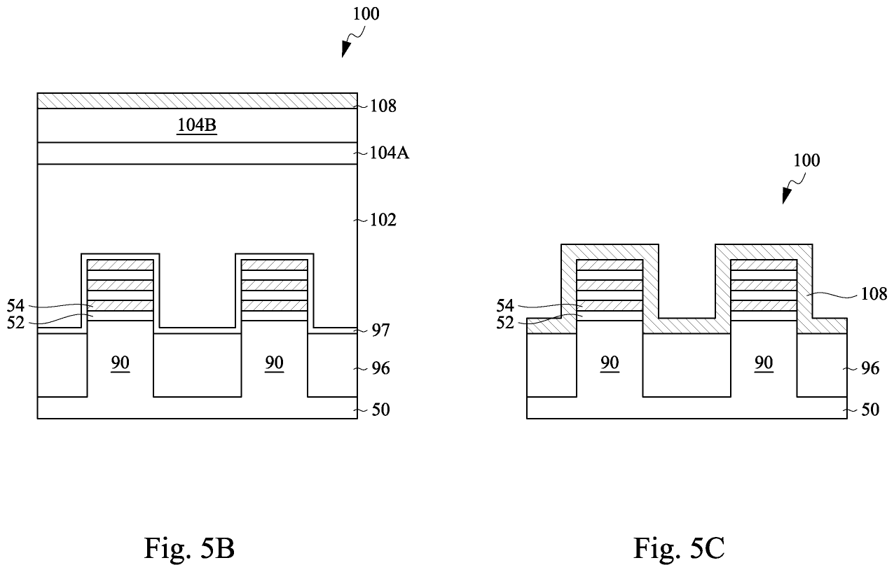

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise described, the same or similar reference numeral in different figures refer to the same or similar component formed by a same or similar formation process using a same or similar material(s). In addition, figures with the same numeral but different alphabets (e.g., FIG. 5A-5C) illustrate different views of the same device at the same stage of processing.

Improved direct bonding between two semiconductor devices is achieved by the disclosed bonding methods. The bonding interface of each semiconductor device is formed by: forming a self-aligned material (SAM) on the surfaces of the conductive features (e.g., bonding pads) at the bonding interface of each semiconductor device; selectively forming a dielectric layer on the surface of the dielectric material around the conductive features; and removing the SAM after selectively forming the dielectric layer. During the direct bonding process, the dielectric layers formed above in each of the semiconductor devices are bonded together first through direct dielectric-to-dielectric bonding, with gaps between the respective conductive features of the semiconductor devices. Next, an annealing process is performed to remove the gaps, such that the respective conductive features of the semiconductor devices come into contact with each other and form direct metal-to-metal bonding. The disclosed bonding methods achieve reliable direct bonding and reduced electrical resistance at the bonding interface, and allow for greater design and routing flexibility.

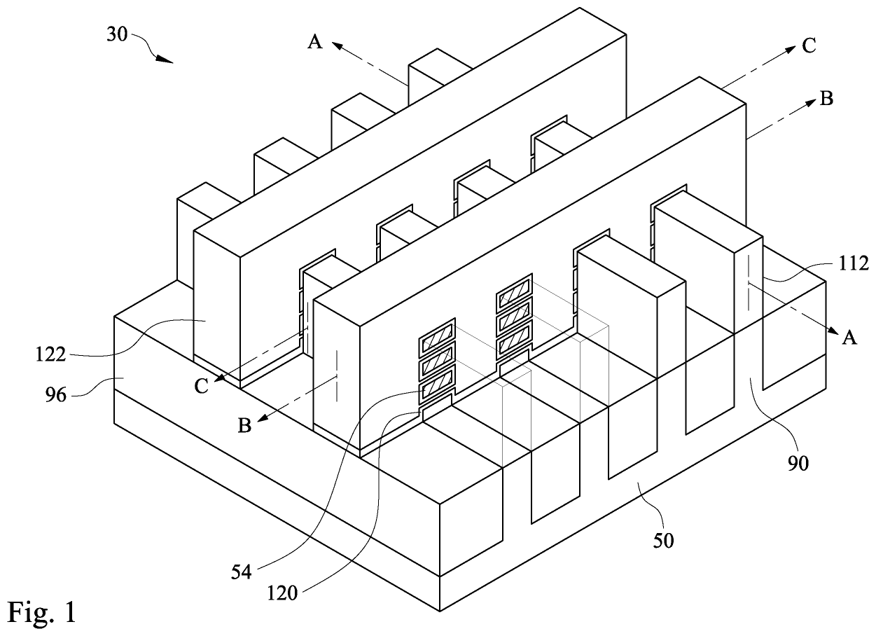

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the fin 90 and is in a direction of, for example, a current flow between the source/drain regions 112 of the NSFET device. Cross-section B-B is perpendicular to cross-section A-A and is along a longitudinal axis of the gate electrode 122. Cross-section C-C is parallel to cross-section B-B and extends through source/drain regions 112 of the NSFET device. Subsequent figures may refer to these reference cross-sections for clarity.

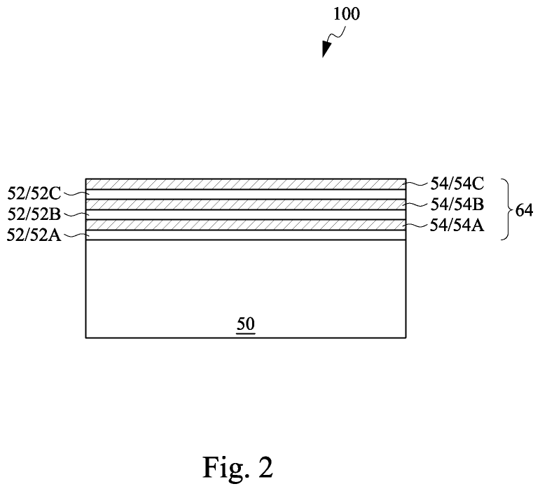

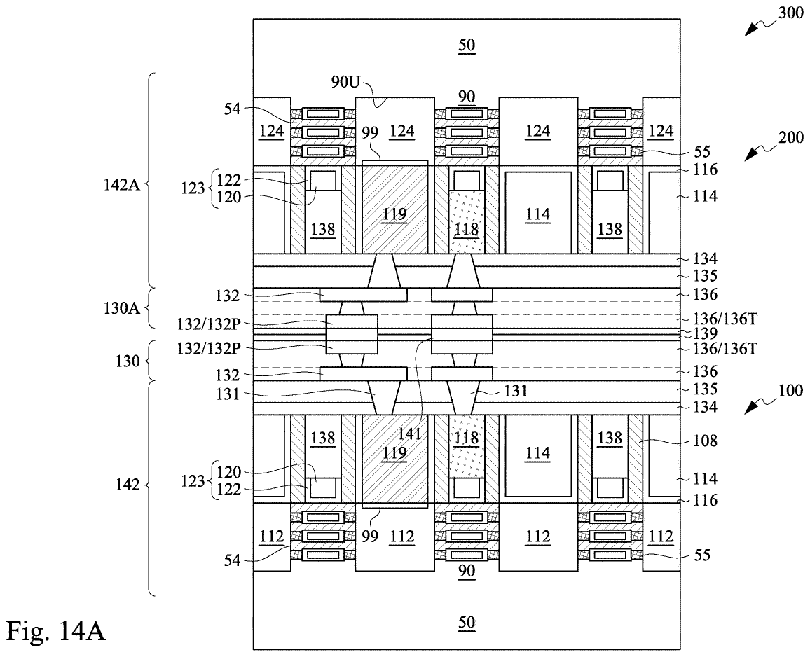

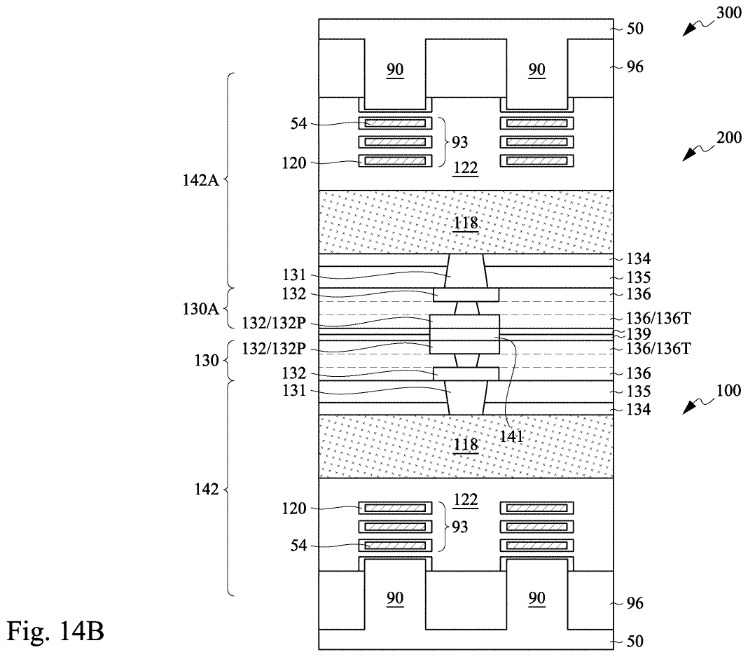

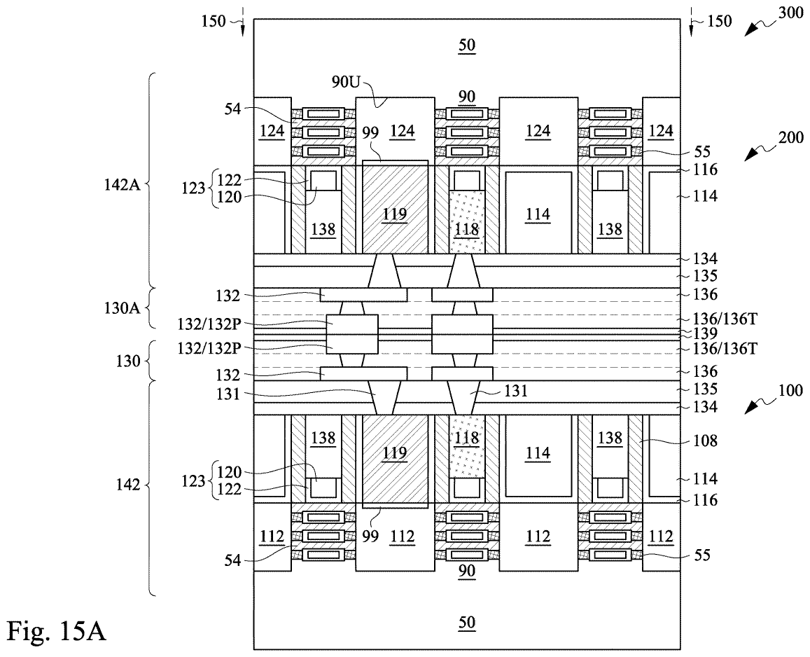

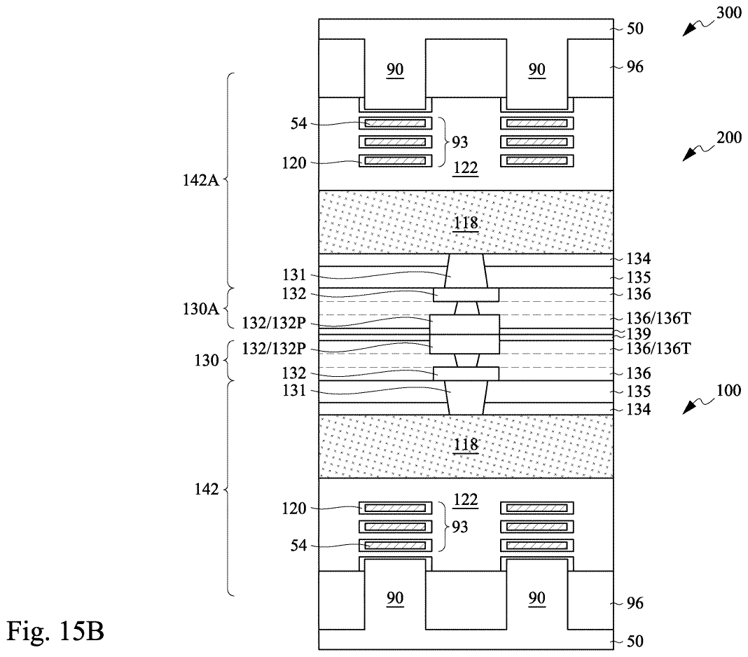

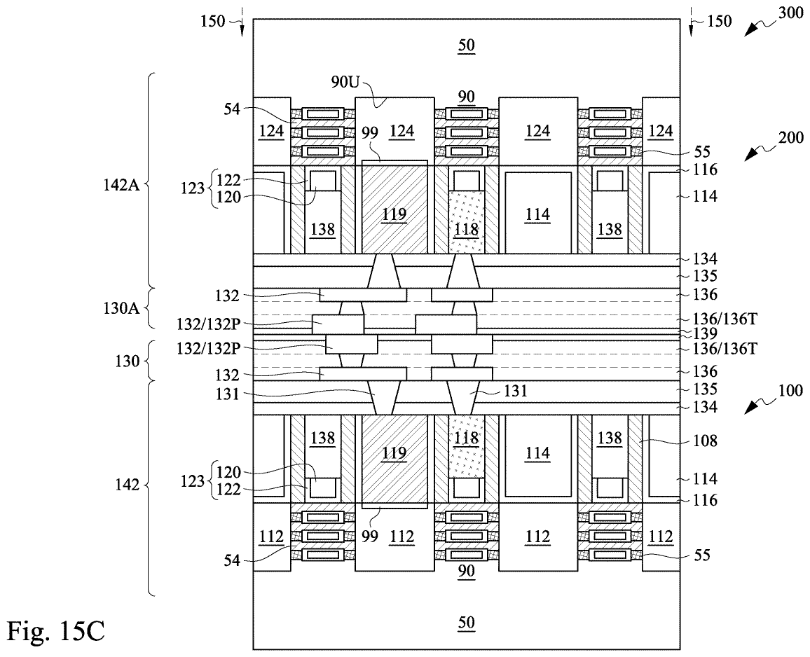

FIGS. 2, 3A, 3B, 4A, 4B, 5A, 5B, 5C, 6A, 6B, 6C, 7A, 7B, 7C, 8A, 8B, 9A, 9B, 10A, 10B, 11A, 11B, 12A, 12B, 13A, 13B, 13C, 14A, 14B, 15A, 15B, and 15C illustrate various views (e.g., cross-sectional view, top view) of a complementary field-effect transistor (CFET) device 300 at various stages of manufacturing, in accordance with an embodiment. In particular, 2, 3A, 3B, 4A, 4B, 5A, 5B, 5C, 6A, 6B, 6C, 7A, 7B, 7C, 8A, 8B, 9A, 9B, 10A, 10B, 11A, 11B, 12A, 12B, 13A, 13B, and 13C illustrate various views (e.g., cross-sectional view, top view) of an NSFET device 100 at various stages of processing, in an embodiment. The NSFET device 100 is then bonded to another NSFET device 200 to form the CFET device 300, as illustrated by the cross-sectional views of FIGS. 14A, 14B, 15A, 15B, and 15C.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the second semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. In some embodiments, the second semiconductor material 54 (e.g., silicon) may be used to form both n-type or p-type FETs, and the first semiconductor material 52 is used as a sacrificial material that is removed later. The multi-layer stack 64 (which may also be referred to as an epitaxial material stack) will be patterned to form channel regions of an NSFET in subsequent processing. For example, the multi-layer stack 64 may be patterned and etched to form nanostructures (e.g., nanosheets or nanowires), with the channel regions of the resulting NSFET including nanostructures that are vertically stacked over a fin, and with each nanostructure extending parallel to a major upper surface of the substrate.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

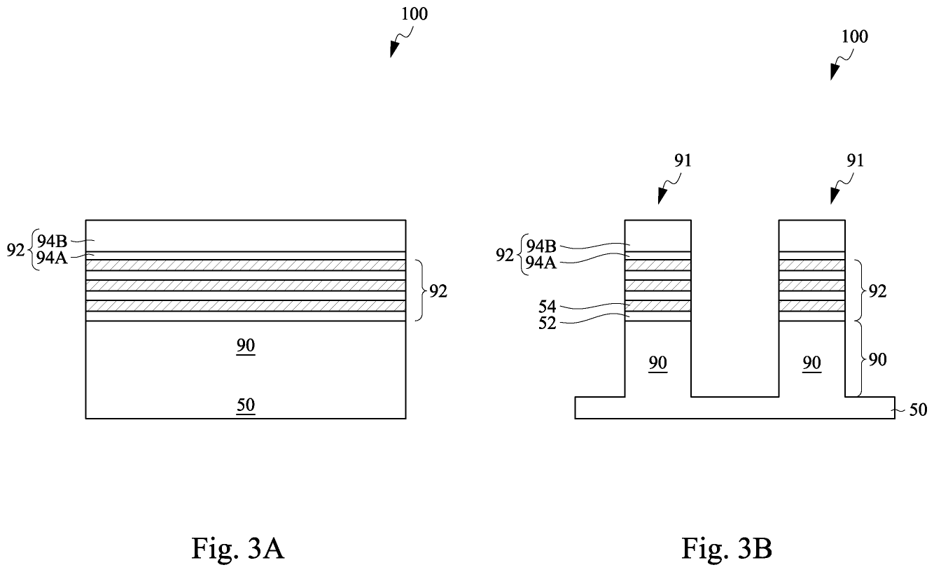

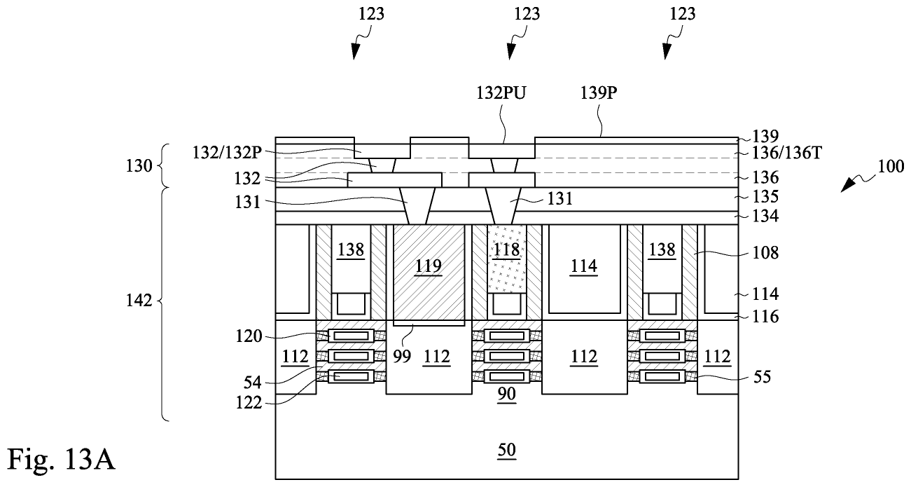

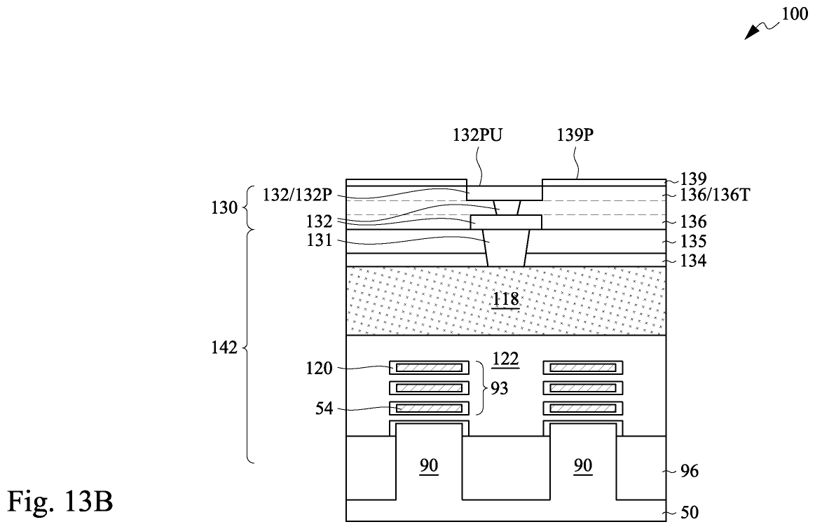

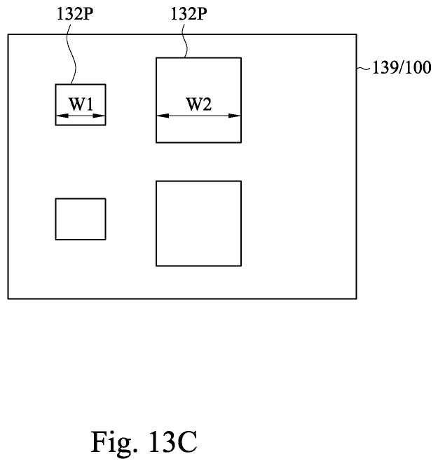

FIGS. 3A, 3B, 4A, 4B, 5A, 5B, 5C, 6A, 6B, 6C, 7A, 7B, 7C, 8A, 8B, 9A, 9B, 10A, 10B, 11A, 11B, 12A, 12B, 13A, 13B, and 13C illustrate various views (e.g., cross-sectional view, top view) of the NSFET device 100 at subsequent stages of manufacturing, in accordance with an embodiment. FIGS. 3A, 4A, 5A, 6A, 7A, 8A, 9A, 10A, 11A, 12A, and 13A are cross-sectional views along cross-section A-A in FIG. 1. FIGS. 3B, 4B, 5B, 6B, 7B, 8B, 9B, 10B, 11B, 12B, and 13B are cross-sectional views along cross-section B-B in FIG. 1. FIGS. 5C, 6C, and 7C are cross-sectional views along cross-section C-C in FIG. 1. FIG. 13C illustrates a top view of the NSFET device 100 in FIGS. 13A and 13B. The number of fins and the number of gate structures illustrated in the figures are merely non-limiting examples, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. In an embodiment, a sacrificial layer is formed over a substrate and patterned using a photolithography process. Spacers are formed alongside the patterned sacrificial layer using a self-aligned process. The sacrificial layer is then removed, and the remaining spacers are then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etch process, such as a reactive ion etch (RIE), neutral beam etch (NBE), the like, or a combination thereof. The etching is an anisotropic etching process, in some embodiments. After the etching process, the patterned multi-layer stack 64 forms the layer stacks 92, and the patterned portion of the substrate 50 forms the fins 90, as illustrated in FIGS. 3A and 3B. The unetched lower portion of the substrate 50 is referred to as substrate 50 in FIGS. 3A and 3B (and subsequent figures). Therefore, in the illustrated embodiment, the layer stack 92 also includes alternating layers of the first semiconductor material 52 and the second semiconductor material 54, and the fin 90 is formed of a same material (e.g., silicon) as the substrate 50.

The fins 90 and the layer stacks 92 in FIG. 3B are illustrated to have substantially perpendicular sidewalls (e.g. perpendicular to the major upper surface of the substrate 50). The shapes of the fins 90 and the layer stacks 92 illustrated in FIG. 3B are merely non-limiting examples. The fins 90 and the layer stacks 92 may have sloped sidewalls (e.g., having trapezoidal cross-sections). The sloped sidewalls may be formed due to the properties of the anisotropic etching process used to form the fins 90 and the layer stacks 92. For example, the etching capability of the anisotropic etching process may decrease along the downward vertical direction of FIG. 3B, which may result in the sloped sidewalls for the fins 90 and the layer stacks 92.

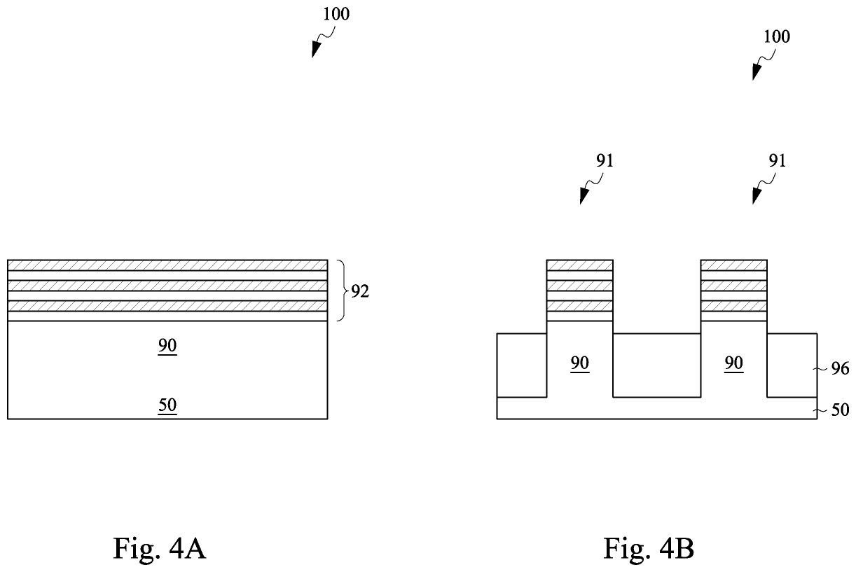

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. The removal process also removes the mask 94, in the illustrated embodiment. In some embodiments, a planarization process such as a chemical mechanical planarization (CMP) process, an etch back process, combinations thereof, or the like, may be utilized. The planarization process exposes the layer stacks 92 such that top surfaces of the layer stacks 92 and the insulation material are level after the planarization process is completed. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than other materials, such as the materials of the fin 90 and the layer stack 92). For example, a chemical oxide removal with a suitable etchant such as dilute hydrofluoric (dHF) acid may be used.

Next, in FIGS. 5A-5C, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gates 102 and the dummy gate dielectrics 97 are collectively referred to as dummy gate structures 101.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

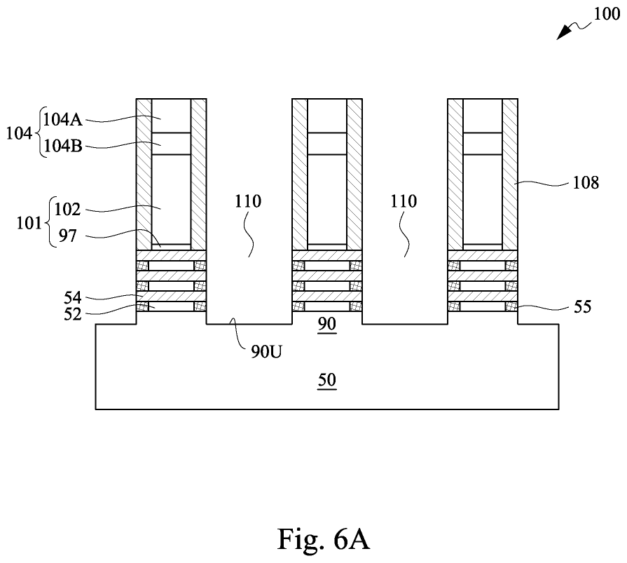

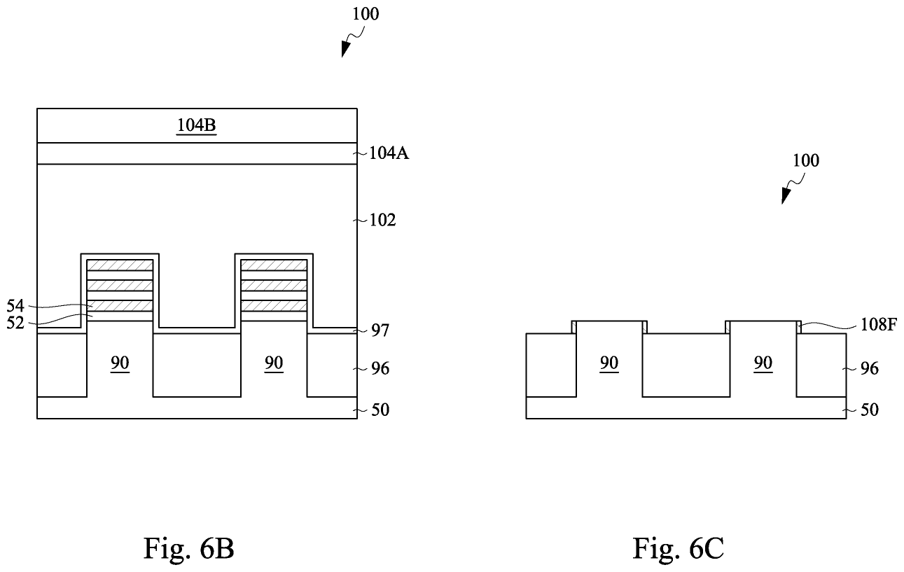

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections B-B and C-C in FIG. 1, respectively. Unless otherwise specified, subsequent figures with alphabets A, B and C (e.g., FIGS. 6A, 6B, and 6C) illustrate cross-sectional views along the same cross-sections as FIGS. 5A, 5B, and 5C, respectively.

Next, in FIGS. 6A-6C, the gate spacer layer 108 is etched by an anisotropic etching process to form gate spacers 108. The anisotropic etching process may remove horizontal portions of the gate spacer layer 108 (e.g., portions over the STI regions 96 and the dummy gates structures 101), with remaining vertical portions of the gate spacer layer 108 (e.g., portions along sidewalls of the dummy gate structures 101) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities between about 1E15/cm³ and about 1E16/cm³. An anneal process may be used to activate the implanted impurities.

Next, openings 110 (which may also be referred to as recesses, or source/drain openings) are formed in the layer stacks 92. The openings 110 may extend through the layer stacks 92 and into the fins 90. The openings 110 may be formed by an anisotropic etching process using, e.g., the dummy gate structures 101 and the gate spacers 108 as an etching mask.

After the openings 110 are formed, a selective etching process is performed to recess end portions of the first semiconductor material 52 exposed by the openings 110 without substantially attacking the second semiconductor material 54. After the selective etching process, recesses (also referred to as sidewall recesses) are formed in the first semiconductor material 52 at locations where the removed end portions used to be.

Next, an inner spacer layer is formed (e.g., conformally) in the openings 110 to line sidewalls and bottoms of the openings 110. The inner spacer layer also fills the sidewall recesses of the first semiconductor material 52 formed by the previous selective etching process. The inner spacer layer may be a suitable dielectric material, such as silicon carbonitride (SiCN), silicon oxycarbonitride (SiOCN), or the like, and may be formed by a suitable deposition method such as PVD, CVD, atomic layer deposition (ALD), or the like. Next, an etching process, such as an anisotropic etching process, is performed to remove portions of the inner spacer layer disposed outside the sidewall recesses of the first semiconductor material 52. The remaining portions of the inner spacer layer (e.g., portions disposed inside the sidewall recesses of the first semiconductor material 52) form inner spacers 55. As illustrated in FIG. 6A, the openings 110 expose sidewalls of the second semiconductor material 54, and expose upper surfaces 90U of the fins 90 at the bottoms of the openings 110.

In the example of FIG. 6C, portions of the gate spacer layer 108 disposed on the upper surface of the STI regions 96 between neighboring fins 90 are completely removed by the anisotropic etching process used for forming the gate spacers 108. Remaining portions of the gate spacer layer 108 along the sidewalls of the fins 90 form fin spacers 108F. In FIG. 6C, the upper surface of the STI regions 96 between neighboring fins 90 is illustrated as a flat surface as a non-limiting example. The upper surface of the STI regions 96 between neighboring fins 90 may be curved (e.g., concave), e.g., due to the anisotropic etching process removing upper portions of the STI regions 96.

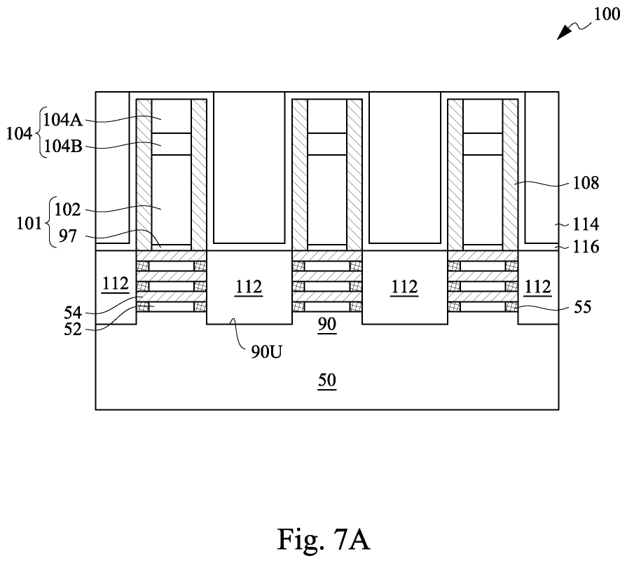

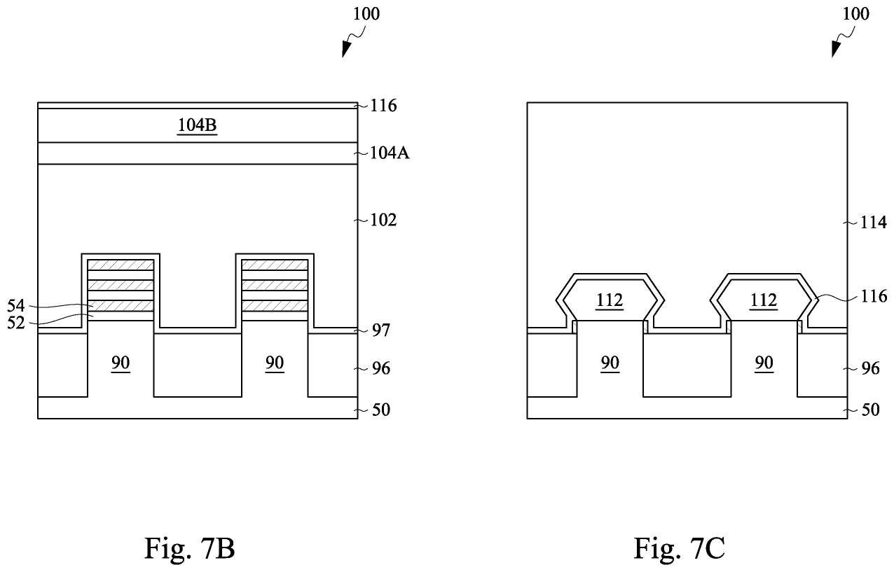

Next, in FIG. 7A-7C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed replacement gate structures of the resulting NSFET device.

The epitaxial source/drain regions 112 are epitaxially grown in the openings 110, in some embodiments. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with a dopant (e.g., n-type impurities or p-type impurities), similar to the process previously discussed for forming lightly-doped source/drain regions, followed by an anneal. The source/drain regions may have an impurity concentration (may also be referred to as a dopant concentration) of between about 1E19/cm³ and about 1E21/cm³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIG. 7C) after the epitaxy process is completed. In other embodiments, these facets cause adjacent epitaxial source/drain regions 112 to merge together.

Next, a contact etch stop layer (CESL) 116 is formed (e.g., conformally) over the source/drain regions 112 and over the dummy gate structures 101, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used.

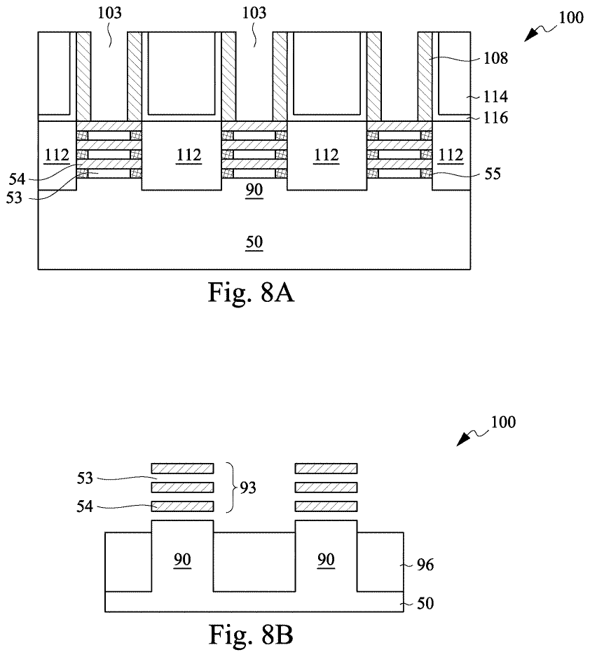

Next, in FIGS. 8A and 8B, the dummy gates 102 and the dummy gate dielectrics 97 are removed. Note that for simplicity, the cross-sectional views along cross-section F-F illustrated in FIG. 5A are not illustrated for processing steps hereinafter, because such cross-sectional views are the same as or similar to FIG. 7C, or may be easily modified from FIG. 7C (e.g., by adding additional layers formed over the first ILD 114).

To remove the dummy gates 102, a planarization process, such as a CMP, is performed to level the top surfaces of the first ILD 114 and the CESL 116 with the top surfaces of the dummy gates 102 and the gate spacers 108. The planarization process may also remove the masks 104 (see FIG. 7A) on the dummy gates 102, and portions of the gate spacers 108 along sidewalls of the masks 104. After the planarization process, top surfaces of the dummy gates 102, the gate spacers 108, the CESL 116, and the first ILD 114 are level. Accordingly, the top surfaces of the dummy gates 102 are exposed through the first ILD 114.

Next, the dummy gates 102 are removed in an etching step(s), so that recesses 103 (also referred to as gate trenches) are formed. In some embodiments, the dummy gates 102 are removed by an anisotropic dry etch process. For example, the etching process may include a dry etch process using reaction gas(es) that selectively etch the dummy gates 102 without etching the first ILD 114 or the gate spacers 108. During the removal of the dummy gates 102, the dummy gate dielectrics 97 may be used as an etch stop layer when the dummy gates 102 are etched. The dummy gate dielectrics 97 may then be removed after the removal of the dummy gates 102. An etching process, such as an isotropic etching process, may be performed to remove the dummy gate dielectrics 97. As illustrated in FIGS. 8A and 8B, the recesses 103 expose the channel regions of the NSFET device 100. The channel regions are disposed between neighboring pairs of the epitaxial source/drain regions 112.

Next, the first semiconductor material 52 (e.g., portions exposed by the recesses 103) is removed to release the second semiconductor material 54. After the first semiconductor material 52 is removed, the second semiconductor material 54 (e.g., portions underlying the dummy gates 102 before the dummy gates 102 are removed) forms a plurality of nanostructures 54. The nanostructures 54 may be collectively referred to as the channel regions 93 or the channel layers 93 of the NSFET device 100 formed. As illustrated in FIGS. 8A and 8B, gaps 53 (e.g., empty spaces) are formed between the nanostructures 54 by the removal of the first semiconductor material 52. In some embodiments, the nanostructures 54 are nanosheets or nanowires, depending on, e.g., the dimensions (e.g., size and/or aspect ratio) of the nanostructures 54.

In some embodiments, the first semiconductor material 52 is removed by a selective etching process using an etchant that is selective to (e.g., having a higher etch rate for) the first semiconductor material 52, such that the first semiconductor material 52 is removed without substantially attacking the second semiconductor material 54. In some embodiments, an isotropic etching process is performed to remove the first semiconductor material 52. The isotropic etching process is performed using an etching gas, and optionally, a carrier gas. The etching gas comprises F₂ and HF, and the carrier gas may be an inert gas such as Ar, He, N₂, combinations thereof, or the like, in some embodiments.

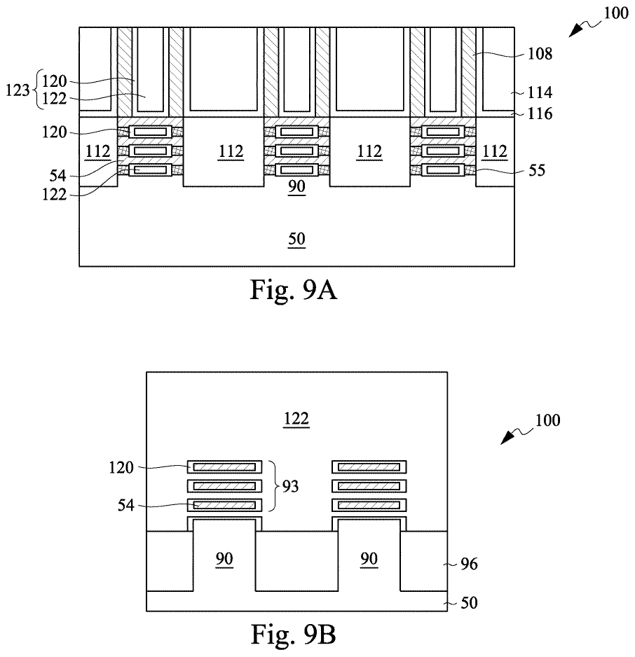

Next, in FIGS. 9A and 9B, a gate dielectric material 120 and a gate electrode material 122 are formed in the recesses 103 to form replacement gate structures 123. The gate dielectric material 120 is deposited conformally in the recesses 103, such as on the top surfaces and the sidewalls of the semiconductor fins 90, and on sidewalls of the gate spacers 108. The gate dielectric material 120 may also be formed on the top surface of the first ILD 114. Notably, the gate dielectric material 120 is formed to wrap around the nanostructures 54. In accordance with some embodiments, the gate dielectric material 120 comprises silicon oxide, silicon nitride, or multilayers thereof. In some embodiments, the gate dielectric material 120 is formed of a high-K dielectric material, and in these embodiments, the gate dielectric material 120 may have a dielectric constant (also referred to as K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, the gate electrode material 122 is deposited over and around the gate dielectric material 120, and fills the remaining portions of the recesses 103. The gate electrode material 122 may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill material (e.g., a fill metal, an electrically conductive material). After the gate electrode material 122 is formed, a planarization process, such as a CMP, may be performed to remove excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120 of the replacement gate structures 123 of the resulting NSFET device 100, respectively. Each gate electrode 122 and the corresponding gate dielectric layer 120 may be collectively referred to as a gate stack, a replacement gate structure, a metal gate structure, or a gate structure. Each gate structure 123 extends around the respective nanostructures 54.

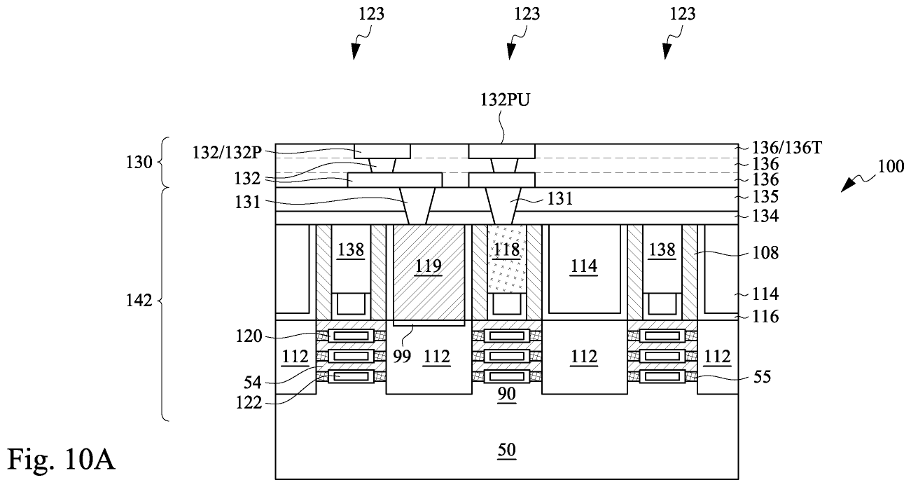

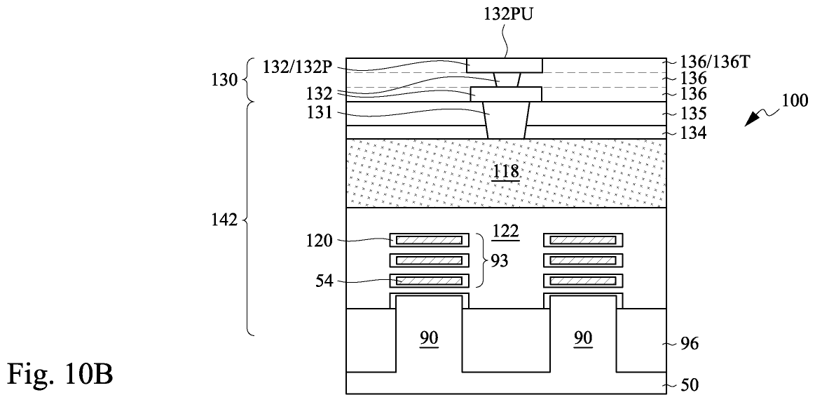

Next, in FIGS. 10A and 10B, gate masks 138 are formed over the replacement gate structures 123. The formation process of the gate masks 138 may include recessing replacement gate structures 123, filling the resulting recesses with a dielectric material such as silicon nitride, silicon carbonitride, silicon oxynitride, silicon oxycarbonitride, or the like, and performing a planarization process to remove excess portions of the dielectric material over the first ILD 114. The remaining portions of the dielectric material form the gate masks 138.

Next, source/drain contact plugs 119 and gate contact plugs 118 are formed to electrically couple to the source/drain regions 112 and the replacement gate structures 123, respectively. In the illustrated embodiments, the source/drain contact plugs 119 and the gate contact plugs 118 are formed in a self-aligned manner, and fill the spaces between opposing sidewalls of the CESL 116 and spaces between opposing sidewalls of the gate spacers 108, respectively.

In some embodiments, one or more anisotropic etching processes are performed to remove portions of the first ILD 114 and portions of the CESL 116 that are disposed over the source/drain regions 112 to form source/drain contact openings and to expose the source/drain regions 112. Similar, one or more anisotropic etching processes may be performed to remove the gate masks 138 to form the gate contact openings that expose the replacement gate structures 123.

The source/drain contact plugs 119 and the gate contact plugs 118 may be formed by filling the source/drain contact openings and the gate contact openings with an electrically conductive material(s), such as tungsten, although other suitable materials such as aluminum, copper, tungsten nitride, rhuthenium, silver, gold, rhodium, molybdenum, nickel, cobalt, cadmium, zinc, alloys of these, combinations thereof, and the like, may alternatively be utilized. A planarization process, such as CMP, may be performed to remove excess portions of the electrically conducive material(s) that are disposed outside of the source/drain contact openings and the gate contact openings. The number and the location of the source/drain contact plugs 119 and the gate contact plugs 118 illustrated in the figures are illustrative and non-limiting, as skilled artisans readily appreciate.

In the illustrated embodiments, silicide regions 99 are formed on the source/drain regions 112 before the source/drain contact openings are filled to form the source/drain contact plugs 119. In some embodiments, the silicide regions 99 are formed by depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the source/drain regions 112, then performing a thermal anneal process to form the silicide regions 99. The un-reacted portions of the deposited metal are then removed, e.g., by an etching process. Although regions 99 are referred to as silicide regions, regions 99 may also be germanide regions, or silicon germanide regions (e.g., regions comprising silicide and germanide).

Next, an etch stop layer (ESL) 134 and a second ILD 135 are formed sequentially over, e.g., the first ILD 114, the replacement gate structures 123, and the gate spacers 108. In some embodiments, The ESL 134 may include a dielectric material having a high etching selectivity from the etching of the second ILD 135, such as aluminum oxide, aluminum nitride, silicon oxycarbide, or the like. The second ILD 135 may be formed using flowable CVD, ALD, or the like, and the material may include PSG, BSG, BPSG, USG, or the like, which may be deposited by any suitable method, such as CVD, PECVD, or the like.

Next, vias 131 are formed to extend through the second ILD 135 and the ESL 134, and to electrically couple to the source/drain contact plugs 119 and gate contact plugs 118. The vias 131 may be formed by forming via openings that extend through the second ILD 135 and the ESL 134, and filling the via openings with an electrically conductive material(s). The electrically conductive material(s) may be the same as or similar to those used for the source/drain contact plugs 119 or the gate contact plugs 118, thus details are not repeated. In some embodiments, a liner layer (e.g., a diffusion barrier layer) may be formed along sidewalls of the via openings before the electrically conductive material(s) fills the via openings. The liner layer may be titanium, tantalum, titanium nitride, tantalum nitride, or the like, and may be formed using any suitable formation methods, such as CVD, ALD, or the like.

In FIGS. 10A and 10B, the layers of the NSFET device 100 disposed between upper portions of the fins 90 and the second ILD 135 are collectively referred to as the device layer 142 of the NSFET device 100.

Still referring to FIGS. 10A and 10B, next, a front-side interconnect structure 130 is formed on the device layer 142. The front-side interconnect structure 130 includes dielectric layers 136 and layers of conductive features 132 in the dielectric layers 136. The dielectric layers 136 may include a suitable dielectric material, such as silicon oxide, silicon nitride, a low-K dielectric material, combinations therefore, or the like, and may be formed by any suitable formation method, such as CVD, PECVD, ALD, combinations thereof, or the like. The conductive features 132 (e.g., electrically conductive features) may include metal lines and vias, which may be formed using, e.g., damascene processes. The conductive features 132 may include diffusion barriers and a metal-containing material (e.g., copper) over the diffusion barriers. The diffusion barrier barriers (may also be referred to as liner layers) may be, e.g., TiN, TaN, TiSiN, TiO, Mn-doped Ru, Mn-doped Co, RuCo, or the like. The metal-containing material may be, e.g., Cu, Co, Ru, Mo, or the like. In some embodiments, the topmost conductive features 132 (e.g., the conductive features 132 in a topmost dielectric layer 136T distal from the device layer 142) may include conductive features 132P (e.g., bond pads, or metal patterns used for bonding) used for bonding with another semiconductor device. Therefore, the conductive features 132P may also be referred to as bonding features or bonding structures.

In the illustrated embodiments, the conductive features 132P are exposed at the outermost surface of the front-side interconnect structure 130 distal from the device layer 142. For example, top surfaces 132PU of the conductive features 132P are level (e.g., flush) with the upper surface of the topmost dielectric layer 136T of the front-side interconnect structure 130.

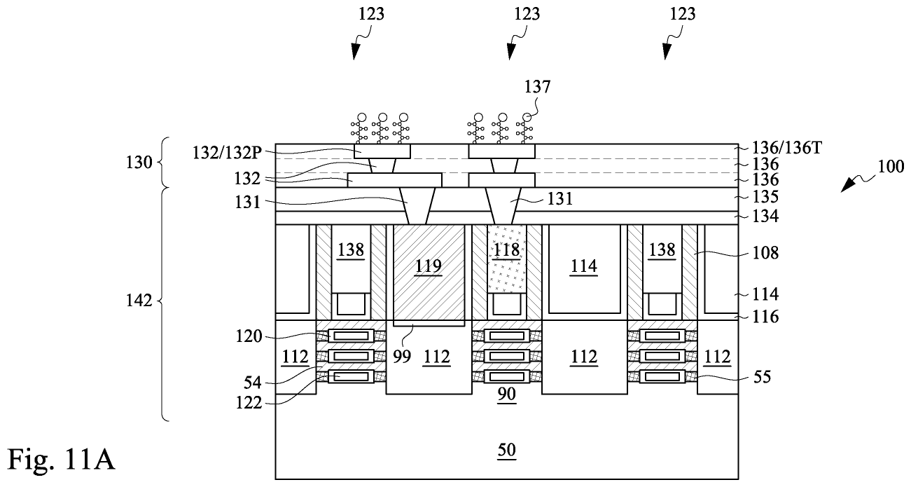

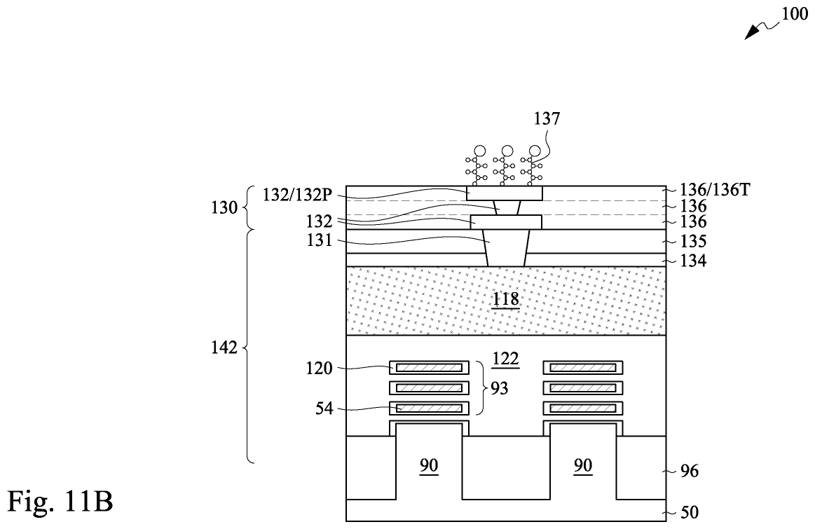

Next, in FIGS. 11A and 11B, a self-aligned material (SAM) 137 is formed on the top surfaces of the conductive features 132P. In the illustrated embodiments, the SAM 137 is selectively formed on the top surfaces of the conductive features 132P. In other words, the SAM 137 covers the top surfaces of the conductive features 132P and exposes the upper surface of the topmost dielectric layer 136T of the front-side interconnect structure 130. The SAM 137 passivates the top surfaces of the conductive features 132P, such that in subsequent processing, a dielectric layer 139 is selectively formed on the upper surface of the topmost dielectric layer 136T, in some embodiments.

In some embodiments, the SAM 137 is formed by applying an alkanethiol on the top surfaces of the conductive features 132P. The alkanethiol may be, e.g., Octadecanethiol (CH₃(CH₂)₁₇SH) or Hexadecanethiol (CH₃(CH₂)₁₅SH). In some embodiments, the SAM 137 is formed by applying a dithiol on the top surfaces of the conductive features 132P. The dithiol may be, e.g., 1,6-Hexanedithiol (HS(CH₂)₆SH). Besides the listed materials, other suitable materials may also be used to form the SAM 137.

In some embodiments, to form the SAM 137, the top surfaces of the conductive features 132P are immersed in a solution that comprises a solute (e.g., the alkanethiol or the dithiol) and a solvent (e.g., ethanol) for a pre-determined period of time. Alkanethiol and dithiol are organic compounds that can form self-assembled monolayers on metal surfaces. Therefore, the SAM 137 is formed (e.g., selectively formed) on the top surfaces of the conductive features 132P. The SAM 137 is a monolayer of an organic material that covers (e.g., passivates) the top surfaces of the conductive features 132P and prevents deposition of another material (e.g., SiO, SiN) on the SAM-passivated top surfaces of the conductive features 132P, in the illustrated embodiments. After the SAM 137 is formed by the above described solution deposition process, the conductive features 132P (or the NSFET device 100) may be rinsed with the solvent (e.g., ethanol), then dried using nitrogen gas, in some embodiments. Besides the solution deposition process, the SAM 137 may also be formed by a vapor deposition process, where the top surfaces of the conductive features 132P are exposed to a dithiol vapor or an alkanethiol vapor for a pre-determined period of time.

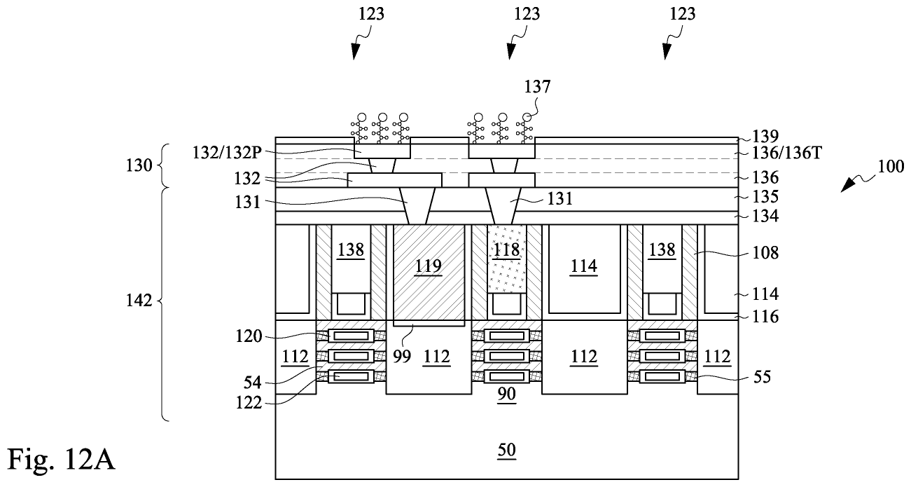

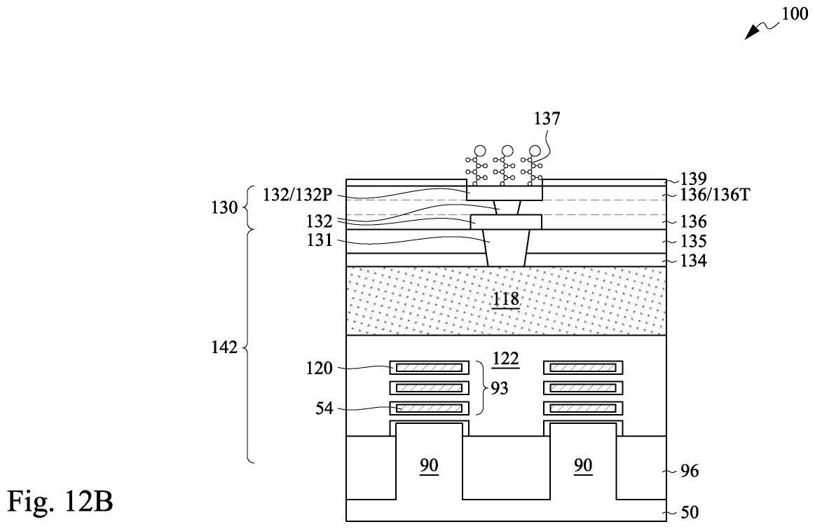

Next, in FIGS. 12A and 12B, a dielectric layer 139 is selectively formed on the upper surface of the topmost dielectric layer 136T of the front-side interconnect structure 130. The dielectric layer 139 may be formed of a suitable dielectric material such as silicon oxide, silicon nitride, a carbon-doped dielectric material (e.g., a carbon-doped silicon oxide), a high-K dielectric material, by a suitable formation method such as CVD, PECVD, ALD, or the like. Note that since the top surfaces of the conductive features 132P are passivated by the SAM 137, the dielectric layer 139 is formed selectively on the upper surface of the topmost dielectric layer 136T, and is not formed on the SAM-passivated top surfaces of the conductive features 132P, in the illustrated embodiments.

In an embodiment, the dielectric layer 139 and the dielectric layers 136 of the front-side interconnect structure 130 are formed of different dielectric materials. For example, the dielectric layers 136 may be formed of silicon oxide, and the dielectric layer 139 may be formed of silicon nitride, a carbon-doped dielectric material, or a high-K dielectric material. In other embodiments, the dielectric layer 139 and the dielectric layers 136 of the front-side interconnect structure 130 are formed of a same dielectric material.

Next, in FIGS. 13A and 13B, the SAM 137 is removed from the top surfaces 132PU of the conductive features 132P using a suitable removal process. For example, an UV/Ozone treatment, where an ultra-violet (UV) light is shone on the SAM 137 while an ozone gas is applied to the SAM 137, may be used to remove the SAM 137. The UV light breaks down the organic material (e.g., the SAM 137), and the ozone gas oxidizes the organic compounds and reacts with the decomposition products. As another example, an oxygen plasma treatment, where an oxygen plasma is supplied to react with the SAM 137, is performed to remove the SAM 137.

As illustrated in FIGS. 13A and 13B, after the SAM 137 is removed, the top surfaces 132PU of the conductive features 132P are flat surfaces and are recessed from an upper surface 139U of the dielectric layer 139 distal from the device layer 142. In other words, the upper surface 139U of the dielectric layer 139 extends further from the device layer 142 than the top surfaces 132PU of the conductive features 132P. In some embodiments, the upper surfaces 132PU of the conductive features 132P are in a same horizontal plane (e.g., a plane parallel to a major upper surface of the substrate 50), and have a same vertical offset from the upper surface 139U of the dielectric layer 139.

FIG. 13C illustrates a top view of the NSFET device 100 of FIGS. 13A and 13B. In FIG. 13C, a plurality of conductive features 132P are illustrated. The plurality of conductive features 132P are used to bond with another NSFET device 200 (see FIG. 14A) to form a CFET device 300 in subsequent processing. In the example of FIG. 13C, the plurality of conductive features 132P have different dimensions. For example, some of the conductive features 132P may have a width W₁, while other conductive features 132P may have a width W₂ larger than the width W₁. The width W₂ may be larger than the width W₁ by, e.g., 20%, 30%, 40%, 50%, 100%, or even more. The different widths of the conductive features 132P allow for increased degree of freedom in the design and the routing of the NSFET device 100. The number and the location of the conductive patterns 132P illustrated in FIG. 13C are illustrative and non-limiting.

Next, in FIGS. 14A and 14B, the NSFET device 100 is bonded to an NSFET device 200 to form a CFET device 300. The NSFET device 200 is similar to the NSFET device 100 and may be formed using a same or similar formation method. The source/drain regions 124 of the NSFET device 200 has a different conductivity type (e.g., N-type or P-type) from the source/drain regions 112 of the NSFET device 100, in some embodiments. For example, the source/drain regions 112 of the NSFET device 100 may have a first doping type (e.g., doped with a dopant of a first conductivity type, such as N-type), and the source/drain regions 124 of the NSFET device 200 may have a second doping type (e.g., doped with a dopant of a second conductivity type, such as P-type) different from the first doping type. In other words, one of the NSFET devices 100 and 200 may be formed using N-type NSFETs, and the other one of the NSFET devices 100 and 200 may be formed using P-type NSFETs. In other embodiments, the source/drain regions 112 of the NSFET device 100 and the source/drain regions 124 of the NSFET device 200 have a same doping type (e.g., both are doped with N-type or P-type dopant).

In FIGS. 14A and 14B, the layers of the NSFET device 200 disposed between upper portions of the fins 90 and the second ILD 135 are collectively referred to as the device layer 142A of the NSFET device 200. FIGS. 14A and 14B further illustrates the front-side interconnect structure 130A of the NSFET device 200 formed over the device layer 142A.

In FIGS. 14A and 14B, the front-side interconnect structure 130A of the NSFET device 200 is bonded to the front-side interconnect structure 130 of the NSFET device 100 to form the CFET device 300. This bonding scheme is also referred to as front-side to front-side bonding.

In FIGS. 14A and 14B, the dielectric layer 139 of the NSFET device 100 is bonded with the dielectric layer 139 of the NSFET device 200 through dielectric-to-dielectric bonding (also referred to as direct dielectric-to-dielectric bonding), while the conductive features 132P of the NSFET device 100 are spaced apart from the respective conductive features 132P of the NSFET device 200, as illustrated by the gaps 141 (e.g., empty spaces) between the conductive features 132P of the NSFET devices 100 and 200. In other words, the dielectric layers 139 of the NSFET devices 100 and 200 are bonded together before the conductive features 132P of the NSFET devices 100 and 200 are bonded together. The gaps 141 exist because the conductive features 132P of the NSFET device 100 (or 200) are recessed from the upper surface 139U of the dielectric layer 139 of the NSFET device 100 (or 200), as illustrated in FIGS. 13A and 13B.

Next, in FIGS. 15A and 15B, an annealing process is performed by heating the CFET device 300, e.g., to a pre-determined temperature for a pre-determined period of time. Since the conductive features 132P (e.g., metal patterns) have larger coefficient of thermal expansion (CTE) than the dielectric layers 139, the thicknesses of the conductive feature 132P are increased more by the annealing process than those of the dielectric layers 139. After the annealing process is completed, the conductive features 132P of the NSFET device 100 are in contact with the conductive features 132P of the NSFET device 200, and metal-to-metal bonding is formed between the respective conductive features 132P.

Dielectric-to-dielectric bonding and metal-to-metal bonding (also referred to as direct metal-to-metal bonding) are bonding techniques that could be used in a direct bonding process to bond two semiconductor devices together without using an intermediate layer (e.g., solder). The direct bonding process uses dielectric-to-dielectric bonding and/or metal-to-metal bonding to achieve a robust and reliable connection at the interface of two devices. Metal-to-metal bonding involves aligning and applying sufficient pressure on metal surfaces, such as copper or aluminum surfaces, often accompanied by thermal treatment to facilitate atomic diffusion and interfacial adhesion without an intermediate layer (e.g., solder). Dielectric-to-dielectric bonding uses surfaces such as silicon dioxide or other insulating materials, which, when aligned under appropriate conditions (e.g., at an elevated temperature and/or with pressure applied at the surfaces), form bonds through forces such as Van der Waals force or covalent interactions. The direct bonding process is instrumental in creating high-density, low-resistance connections while reducing or minimizing thermal budgets.

In some embodiments, during the dielectric-to-dielectric bonding process in FIGS. 14A and 14B, the NSFET devices 100 and 200 are heated to a first temperature to facilitate the dielectric-to-dielectric bonding. The first temperature is lower than a second temperature of the annealing process performed for metal-to-metal bonding in FIGS. 15A and 15B. The expansion of the conductive features 132P caused by the lower first temperature is not enough to achieve physical contact between the conductive features 132P of the NSFET devices 100 and 200, thus forming the gaps 141 in FIGS. 14A and 14B. At the higher second temperature of the annealing process, the conductive features 132P of the NSFET devices 100 and 200 come into contact and form the metal-to-metal bonding. In some embodiments, the dielectric-to-dielectric bonding process in FIGS. 14A and 14B is performed by applying pressure at the bonding interface without performing a heating process.

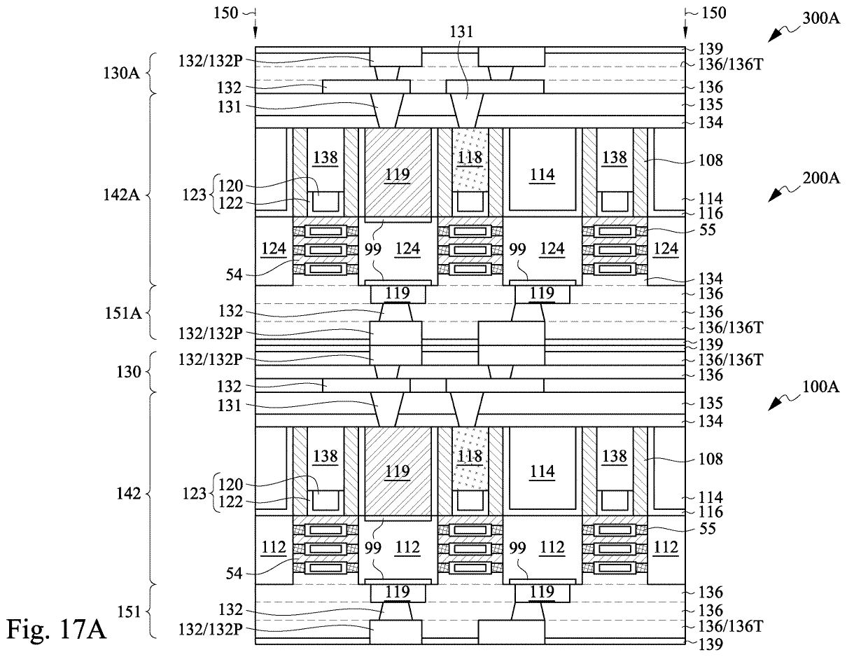

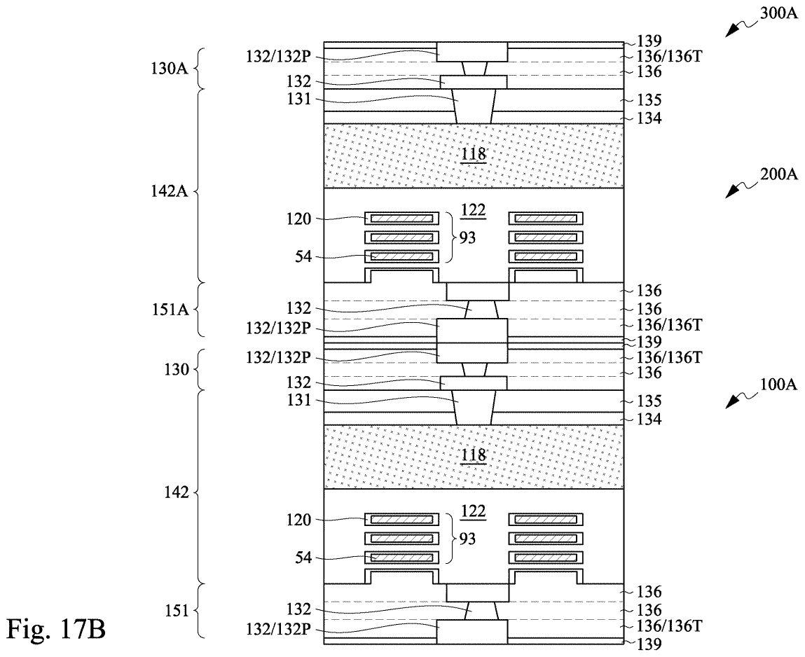

In the example of FIGS. 15A and 15B, there is no misalignment between the conductive features 132P of the NSFET devices 100 and 200. FIG. 15C shows an example where there are misalignment between the conductive features 132P of the NSFET devices 100 and 200. The cross-sectional view of FIG. 15C corresponds to that in FIG. 15A. As illustrated in FIG. 15C, there are lateral offsets between corresponding conductive features 132P of the NSFET devices 100 and 200. The lateral offsets may be caused by, e.g., misalignment introduced during formation of the conductive features 132P of the NSFET devices 100 and 200. As a result of the misalignment, the conductive features 132P of the NSFET device 100 (or 200) are not only in direct contact with respective bonding conductive features 132P of the NSFET device 200 (or 100), but also in direct contact with the dielectric layers 139. In the subsequent disclosed embodiment (e.g., CFET device 300A in FIG. 17A), no misalignment between the conductive features 132P of the NSFET devices 100A and 200A are illustrated, with the understanding that there could be misalignment between the conductive features 132P of the NSFET devices 100A and 200A. These and other variations are fully intended to be included within the scope of the present disclosure.

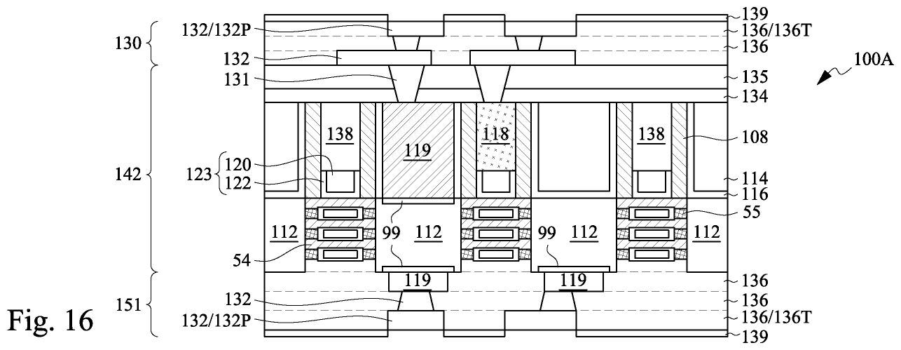

Additional processing may be performed to complete fabrication of the CFET device 300. For example, a backside interconnect structure (see, e.g., 151 in FIG. 16) may be formed at an opposing side of the device layer 142 of the NSFET device 100 from the front-side interconnect structure 130. Similarly, a backside interconnect structure (see, e.g., 151A in FIG. 17A) may be formed at an opposing side of the device layer 142A of the NSFET device 200 from the front-side interconnect structure 130A. The backside interconnect structures may be formed for each of the NSFET devices before the NSFET devices 100 and 200 are bonded together. More details of the backside interconnect structure are discussed hereinafter.

In some embodiments, multiple NSFET devices 100 are formed on a first wafer (e.g., a substrate 50), and multiple NSFET devices 200 are formed on a second wafer (e.g., another substrate 50). After the front-side interconnect structures 130 and 130A are bonded together, a wafer-on-wafer structure is formed that comprises multiple CFET devices 300. Next, a dicing process is performed along dicing regions indicated by the dashed lines 150 in FIG. 15A to separate the wafer-on-wafer structure into individual (e.g., separate) CFET devices 300, where each of the CFET devices 300 includes an NSFET device 100 and an NSFET device 200 stacked vertically (e.g., bonded together). In some embodiments, the NSFET devices 100 and 200 in the CFET device 300 are of different conductivity types. In other embodiments, the NSFET devices 100 and 200 in the CFET device 300 are of the same conductivity type.

FIGS. 16, 17A, and 17B illustrate cross-sectional views of a CFET device 300A at various stages of manufacturing, in accordance with another embodiment. FIG. 16 illustrates the cross-sectional view of an NSFET device 100A. The NSFET device 100A is bonded to another NSFET device 200A in a front-side to backside bonding scheme to form a CFET device 300A, as illustrated in FIGS. 17A and 17B.

FIG. 16 illustrates the cross-sectional view of an NSFET device 100A, in an embodiment. The NSFET device 100A is similar to the NSFET device 100 of FIGS. 13A-13C, but with a backside interconnect structure 151 and a dielectric layer 139 on the backside interconnect structure 151.

In some embodiments, following the processing of FIGS. 13A-13C, a thinning process is performed from the backside of the substrate 50 to thin the substrate. The thinning process may be a grinding process, a CMP process, an etching process, combinations thereof, or the like. The thinning process may remove the substrate 50, the STI regions 96, and lower portions of the fins 90. In some embodiments, the thinning process is stopped when the source/drain regions 112 are exposed. Next, remaining portions of the fins 9o (e.g., portions contacting the replacement gate structures 123) are removed (e.g., by a selective etching process) and replaced by a dielectric layer 143 (e.g., SiO, SiN, or a low-K dielectric material). In FIG. 16, the layers of the NSFET device 100 disposed between the second ILD 135 and the lower surfaces of the source/drain regions 112 are collectively referred to as the device layer 142 of the NSFET device 100A.

Next, the backside interconnect structures 151, which includes dielectric layers 136 and conductive features 132, are formed on the backside of the device layer 142. The backside interconnect structures 151 may include source/drain contact plugs 119 formed in the dielectric layer 136 contacting the dielectric layer 143. Silicide regions 99 are formed at the lower surfaces of the source/drain regions 112 before the source/drain contact plugs 119 are formed, in the illustrated embodiments. The backside interconnect structures 151 also includes conductive features 132P (e.g., bonding pads) embedded in an outermost dielectric layer 136T distal from the device layer 142. Next, following the same or similar processing in FIG. 11A-13C, the SAM 137 is formed on the exposed surfaces of the conductive features 132P of the backside interconnect structure 151. Next, the dielectric layer 139 is selectively formed on the outermost dielectric layer 136T of the backside interconnect structure 151, and the SAM 137 is then removed. Note that the conductive features 132P of the backside interconnect structure 151 are recessed from the upper surface 139U of the dielectric layer 139 formed on the backside interconnect structure 151.

Next, in FIGS. 17A and 17B, the front-side interconnect structure 130 of the NSFET device 100A is bonded to the backside interconnect structure 151A of an NSFET device 200A to form a CFET device 300A. This bonding scheme is also referred to as front-side to backside bonding. The NSFET device 200A is similar to the NSFET device 100A, and may be formed using the same or similar formation method. In some embodiments, the source/drain regions 124 of the NSFET device 200A has a different conductivity type (e.g., N-type or P-type) from the source/drain regions 112 of the NSFET device 100A. In other embodiments, the source/drain regions 112 of the NSFET device 100A and the source/drain regions 124 of the NSFET device 200A have a same conductivity type (e.g., both are doped with N-type or P-type dopant). The device layer, the front-side interconnect structure, and the backside interconnect structure of the NSFET device 200A are labeled as the device layer 142A, the front-side interconnect structure 130A, and the backside interconnect structure 151A in FIGS. 17A and 17B.

The bonding between the NSFET devices 100A and 200A are performed following similar bonding process for forming CFET device 300. For example, the dielectric layer 139 on the front-side interconnect structure 130 of the NSFET device 100A is first bonded to the dielectric layer 139 on the backside interconnect structure 151A of the NSFET device 200A, through dielectric-to-dielectric bonding. After the dielectric-to-dielectric bonding, the conductive features 132P of the front-side interconnect structure 130 of the NSFET device 100A are aligned with respective conductive features 132P of the backside interconnect structure 151A of the NSFET device 200A, but there are gaps (see, e.g., 141 in FIGS. 14A and 14B) between the conductive features 132P of the NSFET devices 100A and 200A. Next, an annealing process is performed to remove the gaps, such that the conductive features 132P of the NSFET devices 100A are in contact with respective conductive features 132P of the NSFET devices 200A to form metal-to-metal bonding. Details are the same or similar as those discussed above, thus not repeated.

FIGS. 17A and 17B illustrate the CFET device 300A after the annealing process and the formation of the metal-to-metal bonding between the respective conductive features 132P of the NSFET devices 100A and 200A. In some embodiments, a dicing process may be performed next along the dicing regions indicated by the dashed lines 150 in FIG. 17A, in order to separate the plurality of CFET devices 300A formed in a wafer-on-wafer structure into a plurality of individual (e.g., separate) CFET devices 300A.

Advantages are achieved by the disclosed embodiments. For example, the disclosed embodiments achieve flat upper surfaces 132PU (see, e.g., FIG. 13A) for the conductive features 132P. During the annealing process, each of the conductive feature 132P expands in volume (e.g., in the thickness direction) and still maintains a flat upper surface 132PU, which flat upper surface 132PU allows for reliable metal-to-metal bonding with a respective conductive feature 132P.

To appreciate the advantage of the disclosed embodiments, consider a reference bonding process that does no use the SAM 137, does not form the dielectric layer 139, and bond the NSFET device 100 and 200 at the outermost surfaces of the interconnect structures. In the reference bonding process, after the front-side interconnect structure 130 (0r backside interconnect structure 151) is formed, an etching process (e.g., a wet etching process) is performed to recess the upper surfaces 132PU of the conductive features 132P. The recessing of the upper surfaces 132PU is needed to accommodate the expansion of the conductive features 132P during the annealing process. However, due to the characteristics of the etching process, the upper surfaces 132PU of the conductive features 132P are not flat after the etching process. Instead, a typical upper surface 132PU of the reference bonding method after the etching process is a curved upper surface, such as a concave upper surface. In addition, the vertical offset between the middle portion and the edge portion of the resulting concave upper surface 132PU may increase with the size (e.g., width) of the conductive feature 132P. Therefore, if the conductive features 132P of the semiconductor device have different widths, the resulting upper surfaces 132PU after the etching process are concave upper surfaces with different depths in the middle. During the annealing process, the concave upper surfaces with different depths result in non-flat bonding surfaces with different heights, which makes it extremely difficult to form reliable metal-to-metal bonding between the conductive features 132P of two semiconductor devices, and may result in large electrical resistance at the metal bonding interfaces due to the poor metal-to-metal bonding.

In contrast, the disclosed embodiments not only achieve flat upper surface 132PU for the conductive features 132P, but also a uniform vertical offset between the upper surfaces 132PU of the conductive features 132P and the upper surface 139U of the dielectric layer 139, regardless of the size (e.g., width) of the conductive features 132P. These features allow reliable metal-to-metal bonding with reduced electrical resistance, which results in improved device reliability, improved production yield, reduced electrical resistance, and reduced power consumption. Another advantage of the disclosed embodiments is that conductive features 132P used for bonding can have different sizes (e.g., widths), which allows for greater flexibility in the design of the device and offers increased routing freedom.

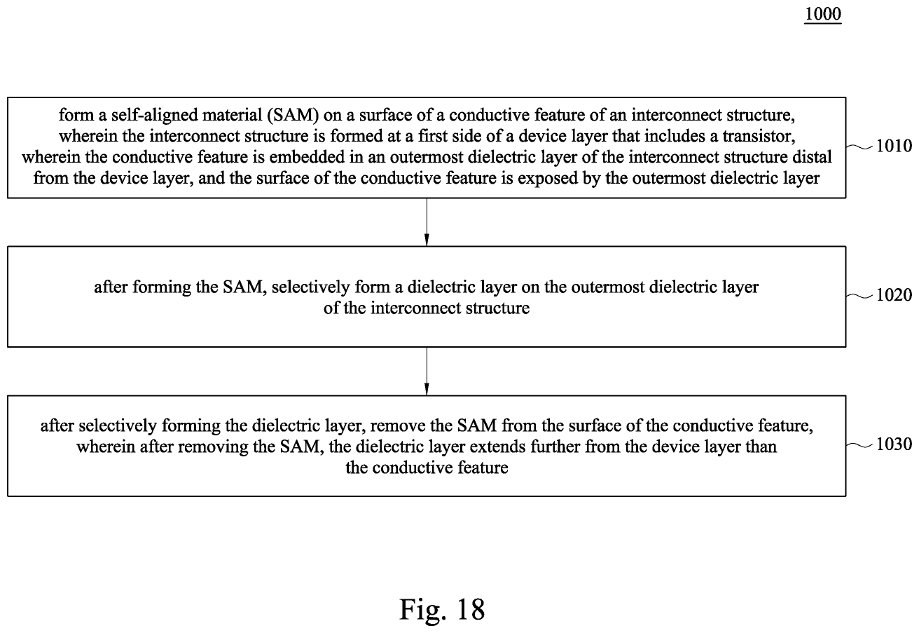

FIG. 18 illustrates a flow chart of a method 1000 of forming a semiconductor device, in accordance with some embodiments. It should be understood that the embodiment method shown in FIG. 18 is merely an example of many possible embodiment methods. One of ordinary skill in the art would recognize many variations, alternatives, and modifications. For example, various steps as illustrated in FIG. 18 may be added, removed, replaced, rearranged, or repeated.

Referring to FIG. 18, at block 1010, a self-aligned material (SAM) is formed on a surface of a conductive feature of an interconnect structure, wherein the interconnect structure is formed at a first side of a device layer that includes a transistor, wherein the conductive feature is embedded in an outermost dielectric layer of the interconnect structure distal from the device layer, and the surface of the conductive feature is exposed by the outermost dielectric layer. At block 1020, after forming the SAM, a dielectric layer is selectively formed on the outermost dielectric layer of the interconnect structure. At block 1030, after selectively forming the dielectric layer, the SAM is removed from the surface of the conductive feature, wherein after removing the SAM, the dielectric layer extends further from the device layer than the conductive feature.

In an embodiment, a method of forming a semiconductor device includes: forming a first device layer over a first substrate, wherein the first device layer comprises a transistor, wherein the transistor comprises a fin protruding above the first substrate, channel regions over the fin, a gate structure around the channel regions, and source/drain region over the fin and on opposing sides of the gate structure; forming a first interconnect structure at a first side of the first device layer and electrically coupled to the transistor, wherein the first interconnect structure comprises a first metal pattern embedded in an outermost dielectric layer of the first interconnect structure distal from the first device layer, wherein a first surface of the first metal pattern is exposed by the outermost dielectric layer of the first interconnect structure; forming a first self-aligned material (SAM) on the first surface of the first metal pattern; after forming the first SAM, selectively forming a first dielectric layer on the outermost dielectric layer of the first interconnect structure; and after selectively forming the first dielectric layer, removing the first SAM from the first surface of the first metal pattern, wherein after removing the first SAM, the first metal pattern is recessed from a surface of the first dielectric layer distal from the first device layer. In an embodiment, forming the first SAM comprises applying an alkanethiol on the first surface of the first metal pattern. In an embodiment, the alkanethiol comprises Octadecanethiol or Hexadecanethiol. In an embodiment, forming the first SAM comprises applying a dithiol on the first surface of the first metal pattern. In an embodiment, the dithiol comprises 1,6-Hexanedithiol. In an embodiment, the method further comprises: after removing the first SAM, bonding the first dielectric layer to a second dielectric layer, wherein the second dielectric layer is pre-formed over a second interconnect structure before the bonding, wherein the second interconnect structure is formed over a second device layer disposed over a second substrate before the bonding, wherein during the bonding, a second metal pattern embedded in an outermost dielectric layer of the second interconnect structure is aligned with the first metal pattern, wherein after the bonding, there is a gap between the first metal pattern and the second metal pattern. In an embodiment, bonding the first dielectric layer comprises bonding the first dielectric layer to the second dielectric layer through dielectric-to-dielectric bonding. In an embodiment, the method further comprises, after the bonding, performing an anneal process, wherein the anneal process removes the gap between the first metal pattern and the second metal pattern, wherein after performing the anneal process, the first metal pattern is bonded to the second metal pattern. In an embodiment, the first metal pattern is bonded to the second metal pattern through metal-to-metal bonding. In an embodiment, before the bonding, the second metal pattern is recessed from a surface of the second dielectric layer distal from the second device layer. In an embodiment, the first device layer is interposed between the first substrate and the first interconnect structure. In an embodiment, the first device layer is formed at a first side of the first substrate, and the first side of the first device layer faces the first substrate, wherein the method further comprising, after forming the first device layer and before forming the first interconnect structure: performing a thinning process from a second opposing side of the first substrate, wherein the thinning process removes the substrate, wherein the first interconnect structure is formed at the first side of the first device layer after performing the thinning process.

In an embodiment, a method of forming a semiconductor device includes: forming a first device layer over a first substrate, wherein the first device layer comprises a first transistor; forming a first interconnect structure at a first side of the first device layer and electrically coupled to the first transistor, wherein the first interconnect structure comprises a first plurality of dielectric layers and a first plurality of conductive features embedded in the first plurality of dielectric layers, wherein a first conductive feature of the first interconnect structure is exposed at a first surface of an outermost dielectric layer of the first interconnect structure distal from the first device layer; covering the first conductive feature with a self-aligned material (SAM), wherein after the covering, the first surface of the outermost dielectric layer of the first interconnect structure is exposed by the SAM; after the covering, selectively forming a first dielectric layer on the first surface of the outermost dielectric layer of the first interconnect structure; and after selectively forming the first dielectric layer, removing the SAM from the first conductive feature, wherein after removing the SAM, the first dielectric layer extends further from the first device layer than the first conductive feature. In an embodiment, covering the first conductive feature comprises selectively forming the SAM on the first conductive feature using an alkanethiol or a dithiol. In an embodiment, the method further comprises, after removing the SAM: bonding the first dielectric layer to a second dielectric layer through dielectric-to-dielectric bonding, wherein the second dielectric layer is pre-formed on a second interconnect structure before the bonding, and the second interconnect structure is formed over a second device layer before the bonding, wherein a second conductive feature of the second interconnect structure is exposed at a second surface of the second interconnect structure distal from the second device layer, wherein during the bonding, the second conductive feature is aligned with the first conductive feature, wherein after the bonding, there is a gap between the first conductive feature and the second conductive feature. In an embodiment, the method further comprises, after the bonding, performing an anneal process to bond the first conductive feature and the second conductive feature through metal-to-metal bonding.

In an embodiment, a method of forming a semiconductor device includes: forming a self-aligned material (SAM) on a surface of a conductive feature of an interconnect structure, wherein the interconnect structure is formed at a first side of a device layer that includes a transistor, wherein the conductive feature is embedded in an outermost dielectric layer of the interconnect structure distal from the device layer, and the surface of the conductive feature is exposed by the outermost dielectric layer; after forming the SAM, selectively forming a dielectric layer on the outermost dielectric layer of the interconnect structure; and after selectively forming the dielectric layer, removing the SAM from the surface of the conductive feature, wherein after removing the SAM, the dielectric layer extends further from the device layer than the conductive feature. In an embodiment, before forming the SAM, the surface of the conductive feature is flush with a surface of the outermost dielectric layer distal from the device layer. In an embodiment, forming the SAM comprises applying an alkanethiol or a dithiol to the surface of the conductive feature, wherein after forming the SAM, the surface of the outermost dielectric layer is exposed by the SAM. In an embodiment, the dielectric layer and the outermost dielectric layer of the interconnect structure are formed of different materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming an electronic component over a substrate;
forming an interconnect structure over and electrically coupled to the electronic component, wherein the interconnect structure comprises dielectric layers and conductive features embedded in the dielectric layers, wherein the conductive features comprise a first conductive feature and a second conductive feature that are embedded in an upper dielectric layer of the dielectric layers distal from the substrate, wherein the first conductive feature has a first width, wherein the second conductive feature has a second width different from the first width, and wherein a first surface of the first conductive feature and a second surface of the second conductive feature are exposed by the upper dielectric layer;
forming a self-aligned material (SAM) on the first surface of the first conductive feature and on the second surface of the second conductive feature;
after forming the SAM, selectively forming a first bonding dielectric layer on the upper dielectric layer, wherein the first surface of the first conductive feature and the second surface of the second conductive feature are free of the first bonding dielectric layer after selectively forming the first bonding dielectric layer; and
after selectively forming the first bonding dielectric layer, removing the SAM from the first surface and the second surface, wherein after removing the SAM, the first surface is recessed from an upper surface of the first bonding dielectric layer distal from the substrate by a first distance, and the second surface is recessed from the upper surface of the first bonding dielectric layer by a second distance, and wherein the first distance and the second distance are the same.

2. The method of claim 1, wherein before forming the SAM, the first surface of the first conductive feature and the second surface of the second conductive feature are flat surfaces that are flush with an upper surface of the upper dielectric layer distal from the substrate, wherein after removing the SAM, the first surface of the first conductive feature and the second surface of the second conductive feature remain flat surfaces.

3. The method of claim 1, wherein the second width is larger than the first width by at least 20%.

4. The method of claim 1, wherein forming the SAM comprises immersing the first surface of the first conductive feature and the second surface of the second conductive feature in a solution that comprises a solute and a solvent.

5. The method of claim 4, wherein the solute comprises an alkanethiol or a dithiol, and the solvent comprises ethanol.

6. The method of claim 1, wherein forming the SAM comprises exposing the first surface of the first conductive feature and the second surface of the second conductive feature to an alkanethiol vapor or a dithiol vapor.

7. The method of claim 1, wherein the SAM is formed as a monolayer of an organic material, wherein during selectively forming the first bonding dielectric layer, the SAM hinders formation of the first bonding dielectric layer on the first surface and the second surface.

8. The method of claim 7, wherein removing the SAM comprises shining an ultra-violet (UV) light on the SAM while supplying an ozone gas to the SAM.

9. The method of claim 1, further comprising, after removing the SAM:
bonding the first bonding dielectric layer to a second bonding dielectric layer through dielectric-to-dielectric bonding, wherein the second bonding dielectric layer is pre-formed on a dielectric layer before the bonding, wherein during the bonding, a third conductive feature and a fourth conductive feature embedded in the dielectric layer are aligned with the first conductive feature and the second conductive feature, respectively, and wherein after the bonding, gaps remain between the first conductive feature and the third conductive feature and between the second conductive feature and the fourth conductive feature.

10. The method of claim 9, further comprising, after bonding the first bonding dielectric layer to the second bonding dielectric layer, performing an anneal process, wherein the anneal process removes the gaps such that the first conductive feature is bonded to the third conductive feature through metal-to-metal bonding and the second conductive feature is bonded to the fourth conductive feature through metal-to-metal bonding.

11. A method of forming a semiconductor device, the method comprising:
forming a first device layer over a first side of a substrate, wherein the first device layer comprises a first transistor;
forming a front-side interconnect structure on a first side of the first device layer facing away from the substrate;
after forming the front-side interconnect structure, thinning the substrate from a second opposing side of the substrate to expose a second side of the first device layer;
forming a backside interconnect structure on the second side of the first device layer, wherein the backside interconnect structure comprises an outermost dielectric layer distal from the first device layer and a first conductive feature embedded in the outermost dielectric layer, and wherein a first surface of the first conductive feature is exposed by the outermost dielectric layer of the backside interconnect structure;
forming a self-aligned material (SAM) on the first surface of the first conductive feature;
after forming the SAM, selectively forming a first bonding dielectric layer on the outermost dielectric layer of the backside interconnect structure; and
after selectively forming the first bonding dielectric layer, removing the SAM from the first surface of the first conductive feature, wherein after removing the SAM, the first bonding dielectric layer extends further from the first device layer than the first conductive feature of the backside interconnect structure.

12. The method of claim 11, wherein thinning the substrate comprises performing a grinding process, a chemical mechanical polishing (CMP) process, an etching process, or a combination thereof.

13. The method of claim 11, wherein thinning the substrate removes the substrate and exposes source/drain regions of the first transistor, and wherein the backside interconnect structure is formed to include source/drain contact plugs that are electrically coupled to the source/drain regions.

14. The method of claim 11, wherein forming the SAM comprises applying an alkanethiol or a dithiol to the first surface of the first conductive feature.

15. The method of claim 11, further comprising, after removing the SAM:
bonding the first bonding dielectric layer to a second bonding dielectric layer through dielectric-to-dielectric bonding, wherein the second bonding dielectric layer is formed on a dielectric layer, wherein the second bonding dielectric layer and the dielectric layer are pre-formed over a second device layer before the bonding, wherein the second device layer comprises a second transistor, wherein during the bonding, a second conductive feature embedded in the dielectric layer is aligned with the first conductive feature, and wherein after the bonding, a gap remains between the first conductive feature and the second conductive feature.

16. The method of claim 15, further comprising, after the bonding, performing an anneal process, wherein after the anneal process, the first conductive feature is in physical contact with the second conductive feature and is bonded to the second conductive feature through metal-to-metal bonding.

17. A method of forming a semiconductor device, the method comprising:
forming a self-aligned material (SAM) on a surface of a first conductive feature, wherein the first conductive feature is embedded in a first dielectric layer disposed over a device layer, wherein the device layer comprises an electronic component, wherein the surface of the first conductive feature distal from the device layer is flush with a surface of the first dielectric layer;
after forming the SAM, selectively forming a first bonding dielectric layer on the first dielectric layer; and
after selectively forming the first bonding dielectric layer, removing the SAM from the surface of the first conductive feature, wherein after removing the SAM, the first bonding dielectric layer extends further from the device layer than the first conductive feature.

18. The method of claim 17, wherein forming the SAM comprises applying an alkanethiol or a dithiol to the surface of the first conductive feature, wherein after forming the SAM, the surface of the first dielectric layer is exposed by the SAM.

19. The method of claim 17, further comprising, after removing the SAM, bonding the first bonding dielectric layer to a second bonding dielectric layer through dielectric-to-dielectric bonding, wherein the second bonding dielectric layer is pre-formed on a second dielectric layer before the bonding, wherein during the bonding, the first conductive feature is aligned with a second conductive feature embedded in the second dielectric layer, wherein after the bonding, there is a gap between the first conductive feature and the second conductive feature.

20. The method of claim 19, further comprising, after the bonding, performing an anneal process, wherein after the anneal process, the first conductive feature expands in volume and physically contacts the second conductive feature.
